(19) United States
(12) Patent Application Publication
(10) Pub. No.: US 2011/0221351 A1
(43) Pub. Date: Sep. 15, 2011

(54) Active matrix organic electroluminescence device and a method of manufacture

(75) Inventors: Yadong Jiang, Chengdu (CN); Junsheng Yu, Chengdu (CN); Lu Li, Chengdu (CN); Lei Zhang, Chengdu (CN)

(73) Assignee: University of Electronic Science and Technology of China

(21) Appl. No.: 12/770,725

(22) Filed: Apr. 30, 2010

(30) Foreign Application Priority Data
Mar. 9, 2010 (CN) 201010120832.9

(51) Int. Cl. G09G 3/12; H01L 21/66

(52) U.S. Cl. 315/169.3; 438/16; 257/E21.521

(57) ABSTRACT

The present invention discloses an active matrix organic electroluminescence device comprising a thin-film transistor, an organic electroluminescence device, and an interlayer deposited between the thin-film transistor and the organic electroluminescence device, wherein the interlayer is made of cationic ultraviolet-curing adhesive comprising epoxy resin or modified epoxy resin, diluting agent, cationic photo initiator. The interlayer solves poor adhesiveness between the driving circuit and the organic electroluminescence device, and improves the moisture and oxygen proof ability. The preparation method is simple, effective, and able to lower the cost and difficulty, and greatly improve the yield rate.

### BACKGROUND OF THE PRESENT INVENTION

1. Field of Invention

The present invention relates to an organic optoelectronic device, and more particularly to an active matrix organic electroluminescence device and a method of manufacture thereof.

2. Description of Related Arts

Optoelectronic technology is a fast developing high-tech industry after microelectronic technique. As the development of the optoelectronic technology, the relevant devices, such as solar cell, optical image sensor, plasma display panel, electroluminescent display, thin-film transistor, LCD panels, and so on, are all developed, which greatly improve the standard and quality of daily life. The wide application of the optoelectronic technology also creates a huge market potential. At present, optoelectronic industry has been the key development area in western countries. Therefore there is worldwide competition in the optoelectronic area.

Organic semi-conductive material has been applied to optoelectronic device, which greatly helps the development of the optoelectronic technology. After the organic electroluminescence device with thin-film sandwich structure is invented in 1987, organic optoelectronic device have been developed much faster than ever before. The organic material is applied to optical probe, solar cell, display device, and so on. By using the organic material, the cost of the optoelectronic device is greatly reduced, and the performance is greatly improved.

Conventionally, in order to obtain active matrix organic electroluminescence device, a method of depositing photoresist between the driving circuit and active matrix organic electroluminescence device is used to insulate. However, this method needs special equipment and is difficult to operate, which results in high cost. On the other hand, the conventional active matrix organic electroluminescence device has another drawback that the organic electroluminescence device is easily splitting off from the driving circuit.

### SUMMARY OF THE PRESENT INVENTION

An object of the present invention is to provide an active matrix organic electroluminescence device and a method of manufacture thereof, which solves poor adhesiveness between the driving circuit and the organic electroluminescence device due to the low surface energy of the TFT (thin film transistor), and improve the ability to proof moisture and oxygen. The preparation method is simple, effective, and able to lower the cost and difficulty, and greatly improves the yield rates.

Accordingly, in order to accomplish the above object, the present invention provides an active matrix organic electroluminescence device comprising a thin-film transistor, an organic electroluminescence device, and an interlayer deposited between the thin-film transistor and the organic electroluminescence device, wherein the interlayer is made of cationic ultraviolet-curing adhesive comprising 95-99.5% epoxy resin or modified epoxy resin, 0.4-4% diluting agent, and 0.1-3% cationic photo initiator.

The diluting agent comprises active epoxy resin diluting agent, cyclic ether, macrolide, and vinyl ether resin monomer. The cationic photo initiator comprises diaryliodonium salt and triaryl iodonium salt.

In the active matrix organic electroluminescence device of the present invention, the interlayer is a single layer structure or double-layer structure or multi-layer structure. The double-layer structure interlayer comprises a lower adhesive deposited on the organic electroluminescence device and an upper adhesive deposited on the lower adhesive, wherein the lower adhesive and upper adhesive have the same or different concentrations and the thickness of the lower adhesive and upper adhesive are the same or different. Multi-layer structure is formed by a plurality of double-layer structures or a plurality of single-layer structures, wherein the number of the double-layer structures is M, and the number of the single-layer structures is N, wherein 100>M>1, 200>N>1.

The method of manufacturing an active matrix organic electroluminescence device comprises steps of:

(1) preprocessing a substrate;

(2) preparing a thin-film transistor on the substrate;

(3) applying interlayer materials onto a surface of the thin-film transistor forming an interlayer, wherein the interlayer material is cationic ultraviolet-curing adhesive comprising 95-99.5% epoxy resin or modified epoxy resin, 0.4-4% diluting agent, and 0.1-3% cationic photo initiator, the diluting agent comprises active epoxy resin diluting agent, cyclic ether, macrolide, and vinyl ether resin monomer, and the cationic photo initiator comprises diaryliodonium salt and triaryl liodonium salt;

(4) photoetching the interlayer forming a pattern thereon;

(5) preparing an organic electroluminescence device on the interlayer;

(6) packaging the organic electroluminescence device; and

(7) testing photoelectric properties and parameters of the organic electroluminescence device;

wherein an ultraviolet-curing process is implemented after step (3) and/or step (5).

In step (3), the interlayer is directly prepared on the thin-film transistor, or after diluted by an organic diluting agent, wherein the interlayer is deposited on the thin-film transistor by a method selected from the group consisting of vacuum coating, ionic cluster beam deposition, ion plating, DC sputtering film, RF sputtering film, ion beam sputtering film, ion beam assisted deposition, plasma enhanced chemical vapor deposition, high-density inductive couple plasma source chemical vapor deposition, catalytic chemical vapor deposition, magnetron sputtering, plating, spin coating, dip coating, inkjet printing, roller coating, and langmuir-blodgett film.

The method of manufacturing an active matrix organic electroluminescence device comprises steps of:

(a) ultrasonic cleaning an organic electroluminescence device with scouring agent, acetone solvent, ethanol solvent, and deionized water, and drying the organic electroluminescence device by blowing nitrogen thereto;

(b) preparing a thin-film transistor on a processed substrate;

(c) stirring an adhesive material diluted by ethanol for 20 hours forming a mixture, wherein adhesive material: ethanol is 1:10, applying the mixture onto a surface of the thin-film transistor in a spining manner for a minute forming a interlayer, wherein the spinning rate is 2000 rounds per second and the thickness of the interlayer is 100 nm, wherein the adhesive material comprises 95˜99.5% epoxy resin or modified epoxy resin, 0.4˜4% diluting agent, and 0.1˜3% cationic photo initiator, the diluting agent comprises active epoxy resin diluting agent, cyclic ether, macrolide, and vinyl ether resin monomer, and the cationic photo initiator comprises diaryliodonium salt and triaryl iodonium salt;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer again for 60 seconds after step (f);

(h) testing photoelectric properties and parameters of the organic electroluminescence device.

The advantages of the present invention are listed as follows. (1) The present invention deposits an interlayer between the organic electroluminescence device and the thin-film transistor for the first time. The material used in the interlayer has good adhesiveness and insulation resistance, which improves the adhesiveness between the organic electroluminescence device and the thin-film transistor so as to improve the performance of the active matrix organic electroluminescence device. (2) The interlayer material is cationic ultraviolet-curing adhesive. The cationic ultraviolet-curing adhesive, after cured, forms a tight structure that can prevent moisture and oxygen penetrating through the interlayer, so as to improve the performance and prolong the lifespan of the device. (3) The proportion of the material and process parameters provided in the present invention can assure the better performance of the device. (4) The manufacturing method provided in the present invention can greatly reduce the cost and process difficulty.

These and other objectives, features, and advantages of the present invention will become apparent from the following detailed description, the accompanying drawings, and the appended claims.

### BRIEF DESCRIPTION OF THE DRAWINGS

FIG. 1 is a perspective view of an active matrix organic electroluminescence device according to a preferred embodiment of the present invention.

FIG. 2 is a perspective view of an active matrix organic electroluminescence device according to the fifth preferred embodiment of the present invention.

### DETAILED DESCRIPTION OF THE PREFERRED EMBODIMENT

The present invention is further explained with detail according to the accompanying drawings.

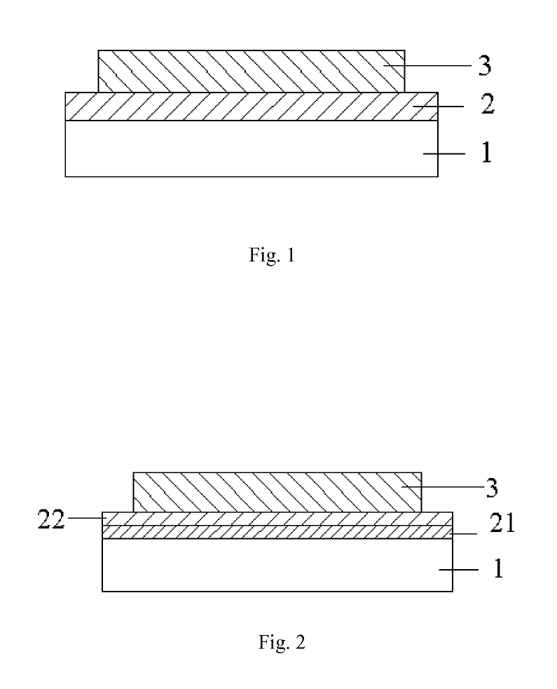

Referring to FIG. 1 of the drawings, the present invention provides an active matrix organic electroluminescence device comprising a thin-film transistor 1, an interlayer 2 deposited on a surface of the thin-film transistor, and an organic electroluminescence device 3 placed on a surface of the interlayer 2.

The thin-film transistor 1 supports the interlayer 2 and the organic electroluminescence device 3. The thin-film transistor 1 has the ability to prevent steam and oxygen from penetrating therethrough, and has good chemical stability and thermal stability.

The interlayer 2 of the present invention between the organic electroluminescence device and the driving circuit is with good properties of smoothness, insulation and adhesive. The interlayer 2 adopts organic adhesive materials.

The organic electroluminescence device 3 of the present invention adopts organic electroluminescence device capable of emitting light of all kinds of colors.

As shown in FIG. 2, a first interlayer 21 of the present invention adopts an ultraviolet-curing adhesive deposited on the thin-film transistor 1. A second interlayer 22 of the present invention adopts an adhesive deposited on the first interlayer 21, which has the same or different components concentrations and thickness from the ultraviolet-curing adhesive used in the first interlayer 21.

The components of the interlayer of the present invention are illustrated hereinafter.

The principle of the cationic ultraviolet-curing system is that the aromatic diazoium salt, aromatic iodonium salt, aromatic sulfonium salt can produce protonic acid, when irradiated by ultraviolet light, and the protonic acid initiates the cationic polymerization of monomer. In the cationic ultraviolet-curing system, the curing shrinkage rate is smaller comparing to the free radical cure system. Furthermore, the cationic ultraviolet-curing system does not have polymerization retardation, and if there is no nucleophilic impurity, once initiated, the polymerization will carry on for a long time. But the photoinitiator, when irradiated by light, will release protonic acid that will erode the cementitious substrate. Theoretically, all the monomer that can be processed by the cationic polymerization can be used for cationic cure. However, the commonly used monomer is all kinds of epoxy resin or modified epoxy resin. All kinds of active epoxy resin diluting agent and all kinds of cyclic ether, macrolide, and vinyl ether resin monomers can be used as diluting agent of the photocuring resin. Cationic photoinitiator comprises diaryliodonium salt, triaryl iodonium salt, triarylsulfonium salt, triarylselenium salt, and so on. At present, many researches on this system are done. For example, it is reported that fluorine-containing mixed resin and no fluorine-containing mixed resin are initiated by the cationic photoinitiator to produce accurate adhesive with low shrinkage rate and adjustable refractive rate. The adhesive produced by the epoxy initiated by the cationic is not eroded under 85° C. and 95% relative humidity for 96 hours. The aliphatic series and bisphenol D mixed epoxy resin initiated by sulfonium salt can produce adhesive with low expansion coefficient and good moisture resistance.
1. Diphenyl (2,4,6-trimethylbenzoyl) phosphine oxide (TPO)
2. Iron Arene Salts, organic Aluminium Complex/silane system, Dialkyl benzoic methyl Triarylsulfonium salt
3. Triarylsulfonium hexafluorophosphate cationic photoinitiator, Tungoil Modified Phenolic Epoxy (TMPE) Resin, and E-44 epoxy resin

The effects on curing rate under various conditions via the test of gelling rate are studied, and the film structure before and after the photo curing reaction are analyzed via infra-red spectrum. The results show that the category and concentration of the photo initiator can effectively change the curing rate. The activity of 10-(4-Biphenylcarbonyl)-2-isopropyl-9-thioxanthen hexafluorophosphate (Omnicat 550) and 13, 6-Dipentaerythritol ethoxide and 10-(2-carboxymethoxyl-4-Biphenylcarbonyl)-2-isopropyl-9-thioxanthen hexafluorophosphate (Omnicat 650) is better than 4,4-dimethyl-diphenyl liodonium hexafluorophosphate (Omnicat 440), and the activity is directly proportional to the concentration. Photosensitizer such as Anthracene, benzoperoxide (BPO) and so on has photosensitization to the system, but the phenothiazine does not have much photosensitization. Different types of epoxy and Vinyl Ethers active diluting agent have great influence on curing rate. The increasing of concentration of epoxide group will increase the curing rate. There is post-curing phenomenon in this system.

### Example 1

As shown in FIG. 1, the organic electroluminescence device 3 is embodied as a blue organic electroluminescence device. The interlayer 2 adopts single layer ultraviolet-curing adhesive. The thin-film transistor 1 is active matrix driving circuit.

The method of manufacture comprises steps of:

(a) ultrasonic cleaning the organic electroluminescence device with scouring agent, acetone solvent, ethanol solvent, and deionized water, and drying the organic electroluminescence device by blowing nitrogen thereto;

(b) preparing a thin-film transistor on the processed substrate;

(c) stirring an adhesive material diluted by ethanol for 20 hours forming a mixture, wherein adhesive material: ethanol is 1:10, applying the mixture onto a surface of the thin-film transistor in a spinning manner for a minute forming a interlayer, wherein the spinning rate is 2000 rounds per second and the thickness of the interlayer is 100 nm, wherein the adhesive material comprises 96% epoxy resin or modified epoxy resin, 3% diluting agent, and 1% cationic photo initiator;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer for another 60 seconds after step (f);

(h) testing photoelectric properties and parameters of the organic electroluminescence device.

Table 1 shows the comparison of the organic electroluminescence device with interlayer that uses adhesive prepared in this invention and the organic electroluminescence device with interlayer that uses conventional adhesive.

TABLE 1

| | leakage current(μA) | leakage current(μA) |
|---|---|---|
| | of conventional | of interlayer |
| AMOLED SPEC | interlayer | of the invention |
| 1.5 inches 128 × 3 × 128 | 46 | 0.09 |
| 2 inches 128 × 3 × 160 | 75 | 0.21 |
| 4 inches 320 × 3 × 240 | 170 | 3.1 |

### Example 2

As shown in FIG. 1, the organic electroluminescence device 3 is embodied as a blue organic electroluminescence device. The interlayer 2 adopts single layer ultraviolet-curing adhesive. The thin-film transistor 1 is active matrix driving circuit.

The method of manufacture comprises steps of:

(a) ultrasonic cleaning the organic electroluminescence device with scouring agent, acetone solvent, ethanol solvent, and deionized water, and drying the organic electroluminescence device by blowing nitrogen thereto;

(b) preparing a thin-film transistor on the processed substrate;

(c) stirring an adhesive material diluted by ethanol for 20 hours forming a mixture, wherein adhesive material: ethanol is 1:10, applying the mixture onto a surface of the thin-film transistor in a spinning manner for a minute forming a interlayer, wherein the spinning rate is 2000 rounds per second and the thickness of the interlayer is 100 nm, wherein the adhesive material comprises 95% epoxy resin or modified epoxy resin, 4% diluting agent, and 1% cationic photo initiator;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer for another 60 seconds after step (f);

(h) testing photoelectric properties and parameters of the organic electroluminescence device.

### Example 3

As shown in FIG. 1, the organic electroluminescence device 3 is embodied as a blue organic electroluminescence device. The interlayer 2 adopts single layer ultraviolet-curing adhesive. The thin-film transistor 1 is active matrix driving circuit.

The method of manufacture comprises steps of:

(a) ultrasonic cleaning the organic electroluminescence device with scouring agent, acetone solvent, ethanol solvent, and deionized water, and drying the organic electroluminescence device by blowing nitrogen thereto;

(b) preparing a thin-film transistor on the processed substrate;

(c) stirring an adhesive material diluted by ethanol for 20 hours forming a mixture, wherein adhesive material: ethanol is 1:10, applying the mixture onto a surface of the thin-film transistor in a spinning manner for a minute forming a interlayer, wherein the spinning rate is 2000 rounds per second and the thickness of the interlayer is 100 nm, wherein the adhesive material comprises 99.5% epoxy resin or modified epoxy resin, 0.4% diluting agent, and 0.1% cationic photo initiator;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer for another 60 seconds after step (f);

(h) testing photoelectric properties and parameters of the organic electroluminescence device.

### Example 4

As shown in FIG. 1, the organic electroluminescence device 3 is embodied as a green organic electroluminescence device. The interlayer 2 adopts single layer ultraviolet-curing adhesive. The thin-film transistor 1 is an active matrix driving circuit.

The method of manufacture comprises steps of:

(a) ultrasonic cleaning the organic electroluminescence device with scouring agent, acetone solvent, ethanol solvent, and deionized water, and drying the organic electroluminescence device by blowing nitrogen thereto;

(b) preparing a thin-film transistor on a processed substrate;

(c) stirring an adhesive material diluted by ethanol for 20 hours forming a mixture, wherein adhesive material: ethanol is 1:10, applying the mixture onto a surface of the thin-film transistor in a spinning manner for a minute forming a interlayer, wherein the spinning rate is 2000 rounds per second and the thickness of the interlayer is 100 nm, wherein the adhesive material comprises 95% epoxy resin or modified epoxy resin, 2% diluting agent, and 3% cationic photo initiator;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer for another 60 seconds after step (f);

(h) testing photoelectric properties and parameters of the organic electroluminescence device.

### Example 5

As shown in FIG. 1, the organic electroluminescence device 3 is embodied as a red organic electroluminescence device. The interlayer 2 adopts single layer ultraviolet-curing adhesive. The thin-film transistor 1 is an active matrix driving circuit.

The method of manufacture comprises steps of:

(a) ultrasonic cleaning the organic electroluminescence device with scouring agent, acetone solvent, ethanol solvent, and deionized water, and drying the organic electroluminescence device by blowing nitrogen thereto;

(b) preparing a thin-film transistor on a processed substrate;

(c) stirring an adhesive material diluted by ethanol for 20 hours forming a mixture, wherein adhesive material: ethanol is 1:10, applying the mixture onto a surface of the thin-film transistor in a spinning manner for a minute forming a interlayer, wherein the spinning rate is 2000 rounds per second and the thickness of the interlayer is 100 nm;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer for another 60 seconds after step (f);

(h) testing photoelectric properties and parameters of the organic electroluminescence device.

### Example 6

As shown in FIG. 1, the organic electroluminescence device 3 is embodied as a multicolor organic electroluminescence device. The interlayer 2 adopts single layer ultraviolet-curing adhesive. The thin-film transistor 1 is an active matrix driving circuit.

The method of manufacture comprises steps of:

(a) ultrasonic cleaning the organic electroluminescence device with scouring agent, acetone solvent, ethanol solvent, and deionized water, and drying the organic electroluminescence device by blowing nitrogen thereto;

(b) preparing a thin-film transistor on a processed substrate;

(c) stirring an adhesive material diluted by ethanol for 20 hours forming a mixture, wherein adhesive material: ethanol is 1:10, applying the mixture onto a surface of the thin-film transistor in a spinning manner for a minute forming a interlayer, wherein the spinning rate is 2000 rounds per second and the thickness of the interlayer is 100 nm;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer for another 60 seconds after step (f);

(i) testing photoelectric properties and parameters of the organic electroluminescence device.

### Example 7

As shown in FIG. 1, the organic electroluminescence device 3 is embodied as a multicolor organic electroluminescence device. The interlayer 2 adopts single layer ultraviolet-curing adhesive. The thin-film transistor 1 is an active matrix driving circuit.

The method of manufacture comprises steps of:

(a) ultrasonic cleaning an organic electroluminescence device with scouring agent, acetone solvent, ethanol solvent, and deionized water, and drying the organic electroluminescence device by blowing nitrogen thereto;

(b) preparing a thin-film transistor on a processed substrate;

(c) stirring an adhesive material diluted by ethanol for 20 hours forming a mixture, wherein adhesive material: ethanol is 1:9, applying the mixture onto a surface of the thin-film transistor in a spinning manner for a minute forming a interlayer, wherein the spinning rate is 1000 rounds per second and the thickness of the interlayer is 150 nm;

(d) curing the interlayer with ultraviolet for 30 seconds;

(e) photoetching the interlayer forming a pattern thereon;

(f) preparing the organic electroluminescence device on the interlayer;

(g) curing the organic electroluminescence device on the interlayer for another 60 seconds after step (f);

(i) testing photoelectric properties and parameters of the organic electroluminescence device.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. An active matrix organic electroluminescence device, comprising:
a thin-film transistor,
an organic electroluminescence device,
and an interlayer deposited between the thin-film transistor and the organic electroluminescence device,
wherein the interlayer is made of cationic ultraviolet-curing adhesive comprising 95-99.5% epoxy resin or modified epoxy resin, 0.4-4% diluting agent, and 0.1-3% cationic photo initiator, the diluting agent comprises active epoxy resin diluting agent, cyclic ether, macrolide, vinyl ether resin monomer, and the cationic photo initiator comprises diaryliodonium salt and triaryl iodonium salt.

2. The active matrix organic electroluminescence device, as recited in claim 1, wherein the interlayer is a single layer structure or double-layer structure or multi-layer structure, wherein the double-layer structure interlayer comprises a lower adhesive deposited on the organic electroluminescence device and an upper adhesive deposited on the lower adhesive, wherein the lower adhesive and upper adhesive have the same or different concentrations and the thickness of the lower adhesive and upper adhesive are the same or different, and multi-layer structure is formed by a plurality of double-layer structures or a plurality of single-layer structures, wherein the number of the double-layer structures is M, and the number of the single-layer structures is N, wherein 100>M>1, 200>N>1.

3. The method of manufacturing an active matrix organic electroluminescence device comprises steps of:
(1) preprocessing a substrate;
(2) preparing a thin-film transistor on the substrate;
(3) applying a interlayer material onto a surface of the thin-film transistor forming a interlayer, wherein the interlayer material is cationic ultraviolet-curing adhesive comprising 95-99.5% epoxy resin or modified epoxy resin, 0.4-4% diluting agent, and 0.1-3% cationic photo initiator, the diluting agent comprises active epoxy resin diluting agent, cyclic ether, macrolide, and vinyl ether resin monomer, and the cationic photo initiator comprises diaryliodonium salt and triaryl iodonium salt;
(4) photoetching the interlayer forming a pattern thereon;
(5) preparing an organic electroluminescence device on the interlayer;
(6) packaging the active matrix organic electroluminescence device;
(7) testing photoelectric properties and parameters of the organic electroluminescence device,
wherein an ultraviolet-curing process is implemented after step (3) and/or step (5).

4. The method, as recited in claim 3, wherein in step (3), the interlayer is directly prepared on the thin-film transistor, or after diluted by an organic diluting agent, wherein the interlayer is deposited on the thin-film transistor by a method selected from the group consisting of vacuum coating, ionic cluster beam deposition, ion plating , DC sputtering film, RF sputtering film, ion beam sputtering film, ion beam assisted deposition, plasma enhanced chemical vapor deposition, high-density inductive couple plasma source chemical vapor deposition, catalytic chemical vapor deposition, megnetron sputtering, plating, spin coating, dip coating, Inkjet Printing, roller coating, and langmuir-blodgett film.

5. The method of manufacturing an active matrix organic electroluminescence device comprises steps of:
(a) ultrasonic cleaning an organic electroluminescence device with scouring agent, acetone solvent, ethanol solvent, and deionized water, and drying the organic electroluminescence device by blowing nitrogen thereto;
(b) preparing a thin-film transistor on a processed substrate;
(c) stirring an adhesive material diluted by ethanol for 20 hours forming a mixture, wherein adhesive material: ethanol is 1:10, applying the mixture onto a surface of the thin-film transistor in a spinning manner for a minute forming a interlayer, wherein the spinning rate is 2000 turns per second and the thickness of the interlayer is 100 nm, wherein the adhesive material comprises 95˜99.5% epoxy resin or modified epoxy resin, 0.4˜4% diluting agent, and 0.1˜3% cationic photo initiator, the diluting agent comprises active epoxy resin diluting agent, cyclic ether, macrolide, vinyl ether resin monomer, and the cationic photo initiator comprises diaryliodonium salt and triaryl iodonium salt;
(d) curing the interlayer with ultraviolet for 30 seconds;
(e) photoetching the interlayer forming a pattern thereon;
(f) preparing the organic electroluminescence device on the interlayer;
(g) curing the organic electroluminescence device on the interlayer again after step (f);
(h) testing photoelectric properties and parameters of the organic electroluminescence device.
